(19) United States
(12) Patent Application Publication
(10) Pub. No.: US 2026/0130147 A1
(43) Pub. Date: May 7, 2026

(54) ROBUST EASILY-REMOVED ETCH STOP

(71) Applicant: International Business Machines Corporation, Armonk, NY (US)

(72) Inventors: Aakash Pushp, Santa Clara, CA (US); Oleg Gluschenkov, Tannersville, NY (US); Noel Arellano, Gilroy, CA (US); Slavko N. Rebec, San Jose, CA (US); Rishikesh Krishnan, Cohoes, NY (US); Paul Charles Jamison, Averill Park, NY (US); Ishwar Singh, Sunnyvale, CA (US); Holt Bui, San Jose, CA (US); Anthony Bock Fong, San Jose, CA (US); Teya Topuria, San Jose, CA (US); Eugene Delenia, Gilroy, CA (US)

(21) Appl. No.: 18/937,236

(22) Filed: Nov. 5, 2024

(51) Int. Cl. H01L 21/311; H01L 27/088; H01L 29/06; H01L 29/417; H01L 29/423; H01L 29/66; H01L 29/775; H01L 29/786

(52) U.S. Cl. CPC H10P 50/73; H10D 30/014; H10D 64/258; H10D 30/43; H10D 30/6735; H10D 30/6757; H10D 62/121; H10D 84/83

(57) ABSTRACT

Embodiments of the disclosure are directed to an integrated circuit (IC) that includes a transistor, a dielectric region and an etch stop material. A portion of the etch stop material is between a portion of the dielectric region and a portion of a gate spacer material of the transistor. The etch stop material is soluble responsive to an etch stop removal material selected from the group consisting of water and an acid.

### BACKGROUND

The present disclosure relates in general to fabrication methods and resulting structures for semiconductor devices. More specifically, the present disclosure relates to fabrication methods and resulting structures for selectively incorporating into an integrated circuit (IC) an etch stop material that is robust (e.g., etch-resistant) and easily-removed.

The various processes used to form a micro-chip that will be packaged into an IC fall into four (4) general categories, namely, film deposition, removal/etching, semiconductor doping and patterning/lithography. Deposition is any process that grows, coats, or otherwise transfers a material onto the wafer. Removal/etching is any process that removes material from the wafer. Example removal processes include etch processes (either wet or dry), chemical-mechanical planarization (CMP), and the like.

To control removal/etching operations, so-called “etch stop” layers can be included in IC fabrication processes. In general, an “etch stop” is formed from material configured to prevent specific regions of a semiconductor wafer from being unintentionally removed.

### SUMMARY

Embodiments of the disclosure are directed to an integrated circuit (IC) that includes a transistor, a dielectric region and an etch stop material. A portion of the etch stop material is between a portion of the dielectric region and a portion of a gate spacer material of the transistor. The etch stop material is soluble responsive to an etch stop removal material selected from the group consisting of water and an acid.

Embodiments of the disclosure are directed to an IC fabrication method that includes forming an etch stop material, where a portion of the etch stop material is adjacent a gate spacer of a transistor-under-fabrication (TUF). A dielectric region is formed over the portion of the etch stop material, and an etchant operable to etch a portion of the dielectric region is applied. The gate spacer has a first etch rate responsive to the etchant, the etch stop material has a second etch rate responsive to the etchant, and the second etch rate is greater than the first etch rate. The etch stop material is soluble responsive to an etch stop removal material selected from the group consisting of deionized water and an acid.

Embodiments of the disclosure are directed to an IC fabrication method that includes forming a transistor including a gate spacer and a source or drain (S/D). An etch stop material is formed. A dielectric region is formed over the S/D, where a first portion of the etch stop material is between a portion of the dielectric region and a portion of the gate spacer. A S/D contact trench is formed in the dielectric region by applying an etchant operable to etch the dielectric region. The first portion of the etch stop material prevents the portion of the gate spacer from being contacted by the etchant. The etch stop material is soluble responsive to an etch stop removal material selected from the group consisting of deionized water and an acid

Embodiments of the disclosure are directed to an IC fabrication method that includes forming a transistor including a gate spacer and a S/D. A layer of an etch stop material is conformally deposited. A first dielectric region is formed over the S/D, where a first portion of the layer of the etch stop material is between a portion of the first dielectric region and a portion of the gate spacer. A S/D contact trench is formed in the first dielectric region by applying an etchant operable to etch the first dielectric region. The first portion of the layer of the etch stop material prevents the portion of the gate spacer from being contacted by the etchant. An etch rate of the etch stop material responsive to the etchant is less than an etch rate of the gate spacer responsive to the etchant. The etch stop material is soluble responsive to an etch stop removal material selected from the group consisting of deionized water and an acid. Subsequent to forming the S/D trench, the first portion of the layer of the etch stop material is removed. Subsequent to removing the first portion of the layer of the etch stop material, a second portion of the layer of the etch stop material remains in a final version of the IC.

Embodiments of the disclosure are directed to an IC fabrication method that includes forming a transistor that includes a gate spacer, a S/D, and a gate cap. A layer of an etch stop material is formed. A first dielectric region is formed over the S/D. A first portion of the layer of the etch stop material is between a portion of the first dielectric region and a portion of the gate spacer. A S/D contact trench is formed in the first dielectric region by applying an etchant operable to etch the first dielectric region. The first portion of the layer of the etch stop material prevents the portion of the gate spacer from being contacted by the etchant. An etch rate of the etch stop material responsive to the etchant is less than an etch rate of the gate spacer responsive to the etchant. The etch stop material is soluble responsive to an etch stop removal material selected from the group consisting of water and an acid. Subsequent to forming the S/D trench, the first portion of the layer of the etch stop material is removed. A bottom surface of the gate cap is vertically lower than a top surface of an end region of the second layer of the etch stop material.

Additional features and technical benefits are realized through techniques described herein. Other embodiments and aspects are described in detail herein. For a better understanding, refer to the description and to the drawings.

### BRIEF DESCRIPTION OF THE DRAWINGS

The subject matter which is regarded as embodiments is particularly pointed out and distinctly claimed in the claims at the conclusion of the specification. The foregoing and other features and advantages of the embodiments are apparent from the following detailed description taken in conjunction with the accompanying drawings in which:

FIG. 1 depicts a top-down view of a simplified nanosheet-based reference structure that provides a reference point for the three-dimensional and cross-sectional views (X-view, Y1-view, and Y2-view) shown in FIGS. 5-14;

FIG. 2 depicts a three-dimensional view of a nanosheet field effect transistor (FET) capable of incorporating aspects of the disclosure;

FIG. 3A depicts a simplified diagram illustrating etch resistance characteristics and removability characteristics of an etch-resistant, easily-removed etch stop material (ER-ER-ESM) embodying aspects of the disclosure;

FIG. 3B depicts a table illustrating various properties of an ER-ER-ESM embodying aspect of the disclosure;

FIG. 3C depicts another table illustrating various properties of an ER-ER-ESM embodying aspect of the disclosure;

FIG. 4A depicts a flow diagram illustrating a methodology in accordance with aspects of the disclosure;

FIG. 4B depicts a flow diagram illustrating additional details of how a portion of the methodology depicted in FIG. 4A can be implemented in accordance with aspects of the disclosure;

FIGS. 5-14 depict multiple cross-sectional views of a portion of an IC after application of IC fabrication operations that perform portions of the methodologies shown in FIGS. 4A and 4B, in which:

FIG. 5 depicts cross-sectional views (X-view) of the portion of the IC after initial IC fabrication operations in accordance with aspects of the present disclosure;

FIG. 6 depicts cross-sectional views (X-view) of the portion of the IC after subsequent IC fabrication operations in accordance with aspects of the present disclosure;

FIG. 7 depicts cross-sectional views (X-view) of the portion of the IC after subsequent IC fabrication operations in accordance with aspects of the present disclosure;

FIG. 8 depicts cross-sectional views (X-view) of the portion of the IC after subsequent IC fabrication operations in accordance with aspects of the present disclosure;

FIG. 9 depicts cross-sectional views (X-view) of the portion of the IC after subsequent IC fabrication operations in accordance with aspects of the present disclosure;

FIG. 10 depicts cross-sectional views (X-view) of the portion of the IC after subsequent IC fabrication operations in accordance with aspects of the present disclosure;

FIG. 11 depicts cross-sectional views (X-view) of the portion of the IC after subsequent IC fabrication operations in accordance with aspects of the present disclosure;

FIG. 12 depicts cross-sectional views (X-view) of the portion of the IC after subsequent IC fabrication operations in accordance with aspects of the present disclosure;

FIG. 13A depicts cross-sectional views (X-view) of the portion of the IC after subsequent IC fabrication operations in accordance with aspects of the present disclosure;

FIG. 13B depicts cross-sectional views (X-view) of the portion of the IC after subsequent IC fabrication operations in accordance with aspects of the present disclosure; and FIG. 14 depicts cross-sectional views (Y1-view) of the portion of the IC after subsequent IC fabrication operations in accordance with aspects of the present disclosure;

FIG. 15 depicts a block diagram of a system capable of implementing embodiments of the disclosure; and

FIG. 16 is a process flow of a method of fabricating an IC operable to implement embodiments of the disclosure.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two-or three-digit reference numbers. With minor exceptions, the leftmost digit(s) of each reference number correspond to the figure in which its element is first illustrated.

### DETAILED DESCRIPTION

Embodiments of the disclosure are directed to an IC that includes and utilizes a robust, easily-removed etch stop material in transistors formed in the IC. The transistor includes a source or drain (S/D), a gate spacer, a gate, and various dielectric regions throughout the IC. The robust, easily-removed etch stop is used to protect the gate spacer (e.g., formed from SiN) from being etched during the formation of a S/D contact trench in a dielectric region (e.g., formed from SiO) that is above the S/D region and adjacent to the gate spacer. In a known semiconductor device fabrication operation, and without benefit of aspects of the disclosure, a fluorine-based etchant (e.g., a fluorine RIE such as SF6, C4F8) is used to form a S/D contact trench in the dielectric region that is above the S/D and adjacent the relatively thin gate spacer (e.g., about 5-7 nanometers in lateral thickness). However, in some situations, the difference between the etch selectivity (or etch rate) of the dielectric region and the etch selectivity (or etch rate) of the relatively thin gate spacer to the etchant used to form the S/D contact trench is small enough that the etchant used to form the S/D contact trench can also remove enough of the relatively thin gate spacer to expose portions of the gate to the S/D contact trench. If this occurs, a S/D contact formed in the S/D contact trench will contact both the S/D and the exposed portions of the gate, thereby forming a short circuit, which can lead to unintended behavior or damage to the transistor.

In embodiments of the disclosure, a robust, easily-removed etch stop material is formed between the gate spacer and the dielectric region in which the S/D contact trench is formed. The robust, easily-removed etch stop material protects the gate spacer from being sufficiently etched to expose the gate during formation of the S/D contact trench in the dielectric region. Thus, the robust, easily-removed etch stop material prevents the etchant used to form the S/D contact trench from also removing enough of the gate spacer to expose portions of the gate to the S/D contact trench, which prevents a S/D contact formed in the S/D contact trench from forming a short circuit by contacting both the S/D and the exposed portions of the gate. Subsequent to forming the S/D contact trench, selected portions of the robust, easily-removed contact trench are easily removed, and the S/D contact is formed in the S/D contact trench.

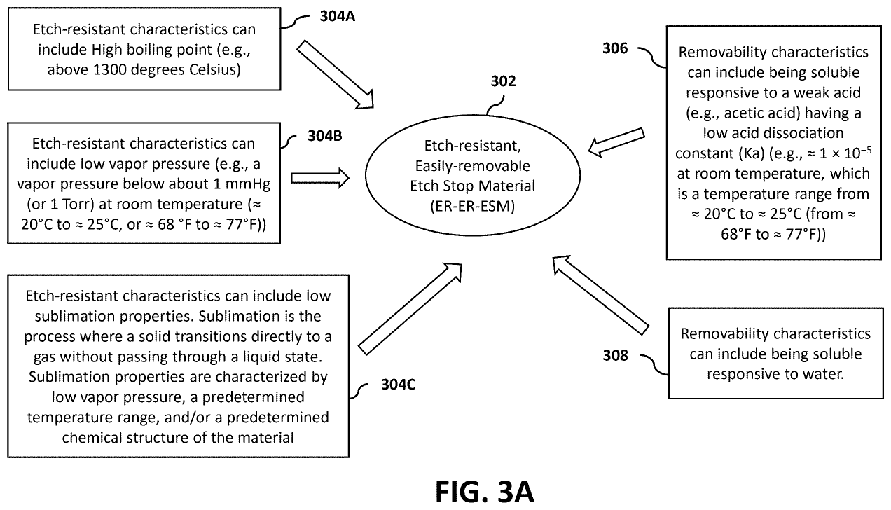

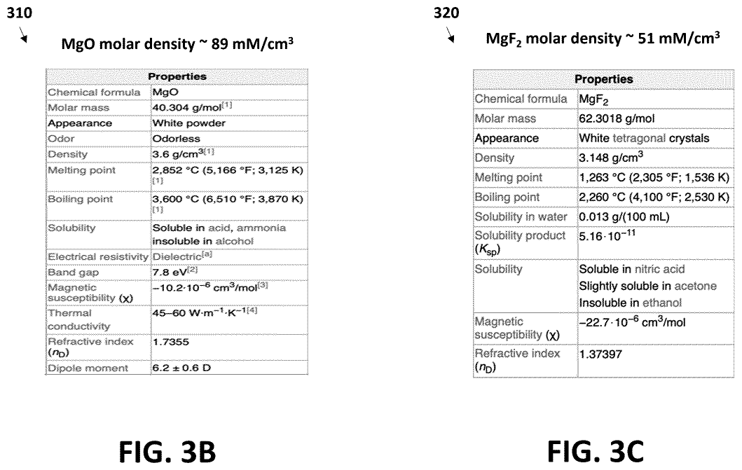

The robust, easily-removed etch stop material used in embodiments of the disclosure is “robust” in that it has one or more etch-resistant characteristics (e.g., high boiling point, low vapor pressure, and/or low sublimation properties) that make it highly resistant to the etchants (e.g., fluoride-based etchants) that are typically used to etch the various materials in the transistor and the IC, including, for example, etchants used to form the previously-described S/D contact trench. The robust, easily-removed etch stop material is “easily-removed” in that it has one or more removability characteristics that make it highly responsive to (e.g., soluble in response to) materials (e.g., a weak acid and/or water) that do not substantially etch or otherwise substantially remove the various materials (e.g., dielectrics, semiconductors, metals, and the like) that are present in the IC. Thus, in this detailed description, embodiments of the robust, easily-removed etch stop material are implemented as an etch-resistant, easily-removed etch stop material (ER-ER-ESM) having one or more of the etch-resistant characteristics and one or more of the removability characteristics (e.g., FIGS. 3A and 3B) described herein. A non-limiting example of an ER-ER-ESM having the etch-resistant characteristics and the removability characteristics described herein include material containing sufficient magnesium (Mg) to provide the material with one or more of the etch-resistant characteristics, as well as materials containing sufficient calcium (Ca) to provide the material with one or more of the removability characteristics, including but not limited to magnesium oxide (MgO) and calcium oxide (CaO). In some embodiments of the disclosure, the ER-ER-ESM is applied as a conformal layer of the ER-ER-ESM. In some embodiments of the disclosure, the etch-resistant characteristics of the conformal layer of the ER-ER-ESM described herein enable the conformal layer of the ER-ER-ESM to provide the etch protections described herein with a relatively thin thickness dimension of less than about 2 nm. In some embodiments of the disclosure, the conformal layer of the ER-ER-ESM can be relatively thicker having a thickness dimension ranging from about 2 nm to about 100 nm.

In embodiments of the disclosure, the ER-ER-ESM can be utilized in the fabrication of transistor devices incorporated into ICs. Such transistor devices include various types of field effect transistors (FETs). FETs are formed using active regions of a wafer. The active regions are defined by isolation regions used to separate and electrically isolate adjacent semiconductor devices. For example, in an IC having a plurality of metal oxide semiconductor field effect transistors (MOSFETs), each MOSFET has a source and a drain that are formed in an active region of a semiconductor layer by introducing n-type or p-type impurities in the layer of semiconductor material. Disposed between the source and the drain is a channel (or body) region. Disposed above the body region is a gate electrode. The gate electrode and the body are spaced apart by a gate dielectric layer.

MOSFET-based ICs are fabricated using so-called complementary metal oxide semiconductor (CMOS) fabrication technologies. In general, CMOS is a technology that uses complementary and symmetrical pairs of p-type and n-type MOSFETs to implement logic functions. The channel region connects the source and the drain, and electrical current flows through the channel region from the source to the drain. The electrical current flow is induced in the channel region by a voltage applied at the gate electrode.

In contemporary semiconductor device fabrication processes, a large number of MOSFETs, such as n-type field effect transistors (NFETs) and p-type field effect transistors (PFETs), are fabricated on a single wafer. Non-planar MOSFET architectures (e.g., fin-type FETs (FinFETs) and nanosheet FETs) can provide increased device density and increased performance over planar MOSFETs. For example, nanosheet FETs, in contrast to conventional planar MOSFETs, include a gate stack that wraps around the full perimeter of multiple stacked and spaced-apart nanosheet channel regions for a reduced device footprint and improved control of channel current flow.

Embodiments of the disclosure are described herein in connection with an application of the ER-ER-ESM to NFETs and PFETs configured as nanosheet FETs. A known method of increasing channel conductivity and decreasing FET size is to form the channel as a nanostructure. For example, a so-called gate-all-around (GAA) nanosheet FET is a known architecture for providing a relatively small FET footprint by forming the channel region as a series of thin nanosheets (e.g., about 3 nm to about 8 nm thick). In a known GAA configuration, a nanosheet-based FET includes a source region, a drain region and stacked, spaced-apart nanosheet channels between the source and drain regions. A gate surrounds the stacked, spaced-apart nanosheet channels and regulates electron flow through the nanosheet channels between the source and drain regions.

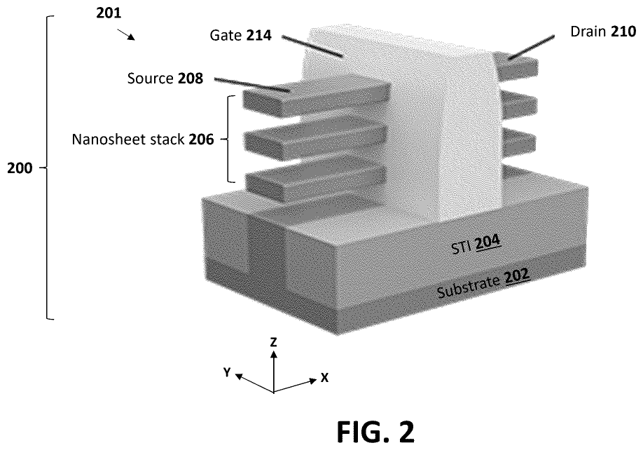

GAA nanosheet FETs (e.g., the GAA nanosheet FET 201 shown in FIG. 2) are fabricated by forming alternating layers of non-sacrificial nanosheets and sacrificial nanosheets. The sacrificial nanosheets are released from the non-sacrificial nanosheets before the FET device is finalized. For n-type FETs, the non-sacrificial nanosheets are typically silicon (Si) and the sacrificial nanosheets are typically silicon germanium (SiGe). For p-type FETs, the non-sacrificial nanosheets can be SiGe and the sacrificial nanosheets can be Si. In some implementations, the non-sacrificial nanosheet of a p-type FET can be SiGe or Si, and the sacrificial nanosheets can be Si or SiGe. Forming the GAA nanosheets from alternating layers of non-sacrificial nanosheets formed from a first type of semiconductor material (e.g., Si for n-type FETs, and SiGe for p-type FETs) and sacrificial nanosheets formed from a second type of semiconductor material (e.g., SiGe for n-type FETs, and Si for p-type FETs) provides superior non-sacrificial electrostatics control, which is necessary for continuously scaling gate lengths down to seven (7) nanometer CMOS technology and below. The use of multiple layered SiGe/Si sacrificial/non-sacrificial nanosheets (or Si/SiGe sacrificial/non-sacrificial nanosheets) to form the channel regions in GAA nanosheet FET semiconductor devices provides desirable device characteristics, including the introduction of strain at the interface between SiGe and Si.

Although embodiments of the disclosure describe an application of the ER-ER-ESM to NFETs and PFETs configured as nanosheet FETs, embodiments of the disclosure can be applied to a variety of transistor architectures.

Accordingly, embodiments of the disclosure are directed to an integrated circuit (IC) that includes a transistor, dielectric regions and an etch stop material. A portion of the etch stop material is between a portion of the dielectric region and a portion of the gate spacer of the transistor. The etch stop material is soluble responsive to an etch stop removal material selected from the group consisting of deionized water and an acid.

Examples of materials that do not provide both etch-resistant characteristics (e.g., one or more of the etch-resistant characteristics 304A, 304B, 304C shown in FIG. 3A) and the removability characteristics (e.g., one or more of the removability characteristics 306, 308 shown in FIG. 3A) in accordance with embodiments of the disclosure include AlOx, HfOx, LaOx, and the like. In particular, AlOx, HfOx, LaOx are difficult to remove post S/D trench etch application in that they do not provide the removability characteristics in accordance with embodiments of the disclosure.

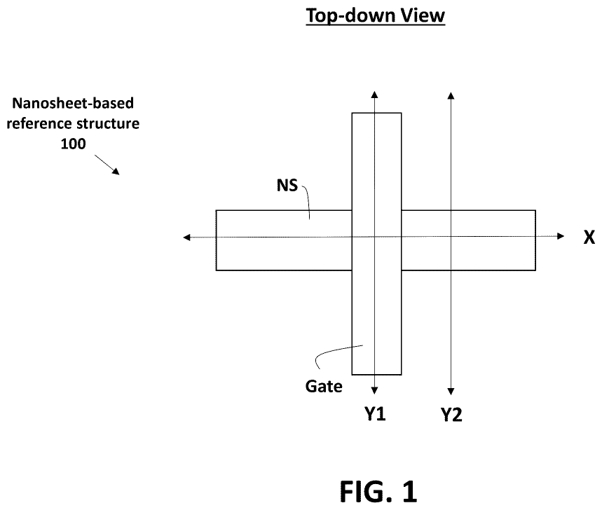

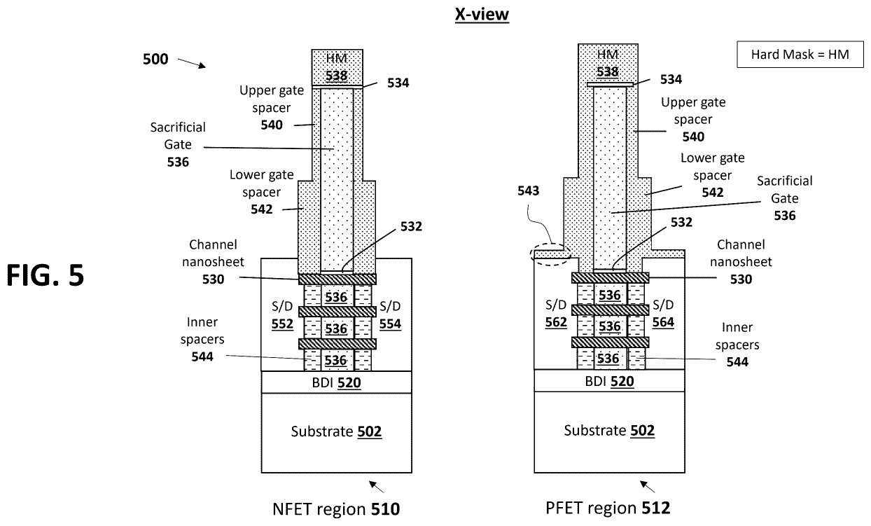

Turning now to a more detailed description of embodiments of the disclosure, FIG. 1 depicts a two-dimensional top-down view of a simplified nanosheet-based reference structure 100 having a nanosheet stack (NS) and a gate (Gate). The nanosheet-based reference structure 100 provides a reference point for the various cross-sectional views (X-view, Y1-view, and Y2-view) that can be used in FIGS. 5-14. More specifically, the X-view is a side view taken along the nanosheets (NS) of the nanosheet-based reference structure 100; the Y1-view is an end view taken along the active Gates of the nanosheet-based reference structure 100; and the Y2-view is a side view taken along the Gates. Although the cross-sectional diagrams depicted in FIGS. 5-14 are two-dimensional, the diagrams depicted in FIGS. 5-14 represent three-dimensional structures. Thus, to assist with visualizing the three-dimensional structures, the top-down view of the nanosheet-based reference structure 100 provides a reference point for the various cross-sectional views (the X-view, the Y1-view, and the Y2-view) that can be used in FIGS. 5-14. It should be noted that, in this detailed description, only the X-view and the Y2-view are used in FIGS. 5-14.

FIG. 2 depicts a three-dimensional view of a portion of an IC wafer 200 having formed thereon a GAA nanosheet FET 201 capable of being used to incorporate a conformal layer of ER-ER-ESM embodying aspects of the disclosure. The basic electrical layout and mode of operation of the GAA nanosheet FET 201 does not differ significantly from a traditional FET. The GAA nanosheet FET 201 is formed on a substrate 202 (e.g., formed from semiconductor material such as silicon), and STI regions 204 electrically isolate the GAA nanosheet FET 201 from other devices on the IC wafer 200. The GAA nanosheet FET 201 includes a nanosheet stack 206 and a gate stack 214, configured and arranged as shown. Each nanosheet stack 206 is formed from spaced-apart nanosheets that extend from one side of the gate stack 214, through the gate stack 214 to an opposite side of the gate stack 214. Each spaced-apart nanosheet can be relatively thin (e.g., about 3 nm to about 8 nm thick) and can have a variety of shapes (e.g., sheets, wires and the like). A first end of the nanosheet stack 206 that is not surrounded by the gate stack 214 forms a source region 208 of the GAA nanosheet FET 201. A second end of the nanosheet stack 206 that is not surrounded by the gate stack 214 forms a drain region 210 of the GAA nanosheet FET 201. A central region of the nanosheet stack 206 that is surrounded by the gate stack 214 forms a channel region (not shown separately) of the GAA nanosheet FET 201. The gate stack 214 controls the source to drain current flow. The dimensions of the nanosheet stack 206 establish the effective channel length for the GAA nanosheet FET 201. For ease of illustration, three individual nanosheets and one gate stack 214 are shown in FIG. 2. In practice, GAA nanosheet FETs can be fabricated having any number of nanosheets in the nanosheet stack 206, and any number of gate stacks 214 formed on the substrate 202. Further, portions of the source region 208 and/or drain region 210 can be reconfigured to improve their electrical conductivity. For instance, portions of nanosheets present in source region 208 and/or drain region 210 can be replaced with a solid block of conductive material (e.g. a heavily doped semiconductor or a metallic compound) in electrical contact the remainder of the nanosheets that form the source region 208 and/or the drain region 210. Additionally, any number of GAA nanosheet FETs can be included in a stacked device configuration in accordance with aspects of the disclosure. The substrate 202 can be silicon, the STI regions 204 can be an oxide (e.g., silicon oxide), and the nanosheet stack 206 can be silicon.

FIG. 3A depicts a simplified diagram illustrating characteristics of a robust, easily-removed etch stop material in accordance with aspects of the disclosure, which is represented in FIG. 3A as an ER-ER-ESM 302 having one or more of the etch-resistant characteristics 304A, 304B, 304C and one or more of the removability characteristics 306, 308. The etch-resistant characteristics 304A, 304B, 304C provide the ER-ER-ESM 302 with a high or strong resistance to the etchants (e.g., fluoride-based) that are typically used to etch the various materials in the transistor and the IC, including, for example, etchants used to form a S/D contact trench in a dielectric material/region (e.g., silicon oxide (SiO)). In embodiments of the disclosure, the ER-ER-ESM 302 is positioned such that it protects the gate spacers (e.g., silicon nitride (SiN)) from also being etched by the etchants (e.g., fluoride-based) that are typically used to etch the various materials in the transistor and the IC, including, for example, the etchants used to form a S/D contact trench in a dielectric material/region (e.g., SiO). Taking the etch used to form a S/D contact trench in a dielectric material/region as an example, because the difference between the etch selectivities (or etch rates) of SiN (the gate spacer) and SiO (the dielectric material/region) to fluoride-based etchants is not large, and because a size of the S/D contact trench can be significantly larger than a thickness of the gate spacers and a distance between adjacent gate spacers, the etchant used to form the S/D contact trench can be applied long enough that portions of the gate spacer are also etched before the S/D contact trench is formed. The etched portions of the gate spacer can be etched sufficiently to expose a portion of the gate to the S/D contact trench. Any one or more of the etch-resistant characteristics 304A, 304B, 304C of the ER-ER-ESM 302 provide the ER-ER-ESM 302 with an etch selectivity or etch rate to the fluoride-based etchant that is significantly less than the etch selectivity or etch rate of the SiN gate spacer to the fluoride-based etchant. Thus, even though a size (e.g., depth) of the S/D contact trench can be significantly larger than a lateral thickness (e.g., about 1 nm to about 5 nm) of the ER-ER-ESM 302, the etchant used to form the S/D contact trench will not be applied long enough that portions of the ER-ER-ESM 302 are also etched sufficiently to expose a portion of the gate spacer.

Any one or more of the etch-resistant characteristics 304A, 304B, 304C provide the ER-ER-ESM 302 with a high resistance to being physically altered in a manner that facilitates its removal from the relevant portion of the IC. The processes that physically alter the ER-ER-ESM 302 include melting processes (e.g., changing a solid to a liquid), sublimation processes (e.g., changing a solid to a gas), and vaporization processes (e.g., changing a liquid to a gas). Each of these processes involves the absorption of heat energy, allowing the molecules to overcome the forces holding them in a solid state. The etch-resistant characteristics 304A can include a boiling point of the ER-ER-ESM 302 at or above a predetermined boiling point. In embodiments of the disclosure, the predetermined boiling point is a high boiling point, where a high boiling point of the ER-ER-ESM 302 is a boiling point above 1300 degrees Celsius in high vacuum conditions, where a high vacuum condition is a vacuum range from 10⁻⁸ Torr to 10⁻¹ Torr.

The etch-resistant characteristics 304B can include a low vapor pressure of the ER-ER-ESM 302. When a material is said to have a “low vapor pressure,” it means that the material tends to evaporate or transition from a liquid to a gas at a slower rate compared to materials with higher vapor pressures. This characteristic indicates that the molecules in the material are more strongly attracted to each other, making it less likely for them to escape into the vapor phase. In embodiments of the disclosure, the etch-resistant characteristics 304B include a vapor pressure at or below a predetermined vapor pressure level. In embodiments of the disclosure, the predetermined vapor pressure level is a low vapor pressure, where a low vapor pressure is a vapor pressure at or below about 1 millimeters of mercury (mmHg) (or about 1 Torr) at room temperature, where room temperature is a temperature range from ≈20° C. to ≈25° C., or from ≈68 ° F. to ≈77° F.

The etch-resistant characteristics 304B can include low sublimation properties of the ER-ER-ESM 302. Sublimation is the process where a solid transitions directly to a gas without passing through a liquid state. The sublimation properties of a material describe how easily it can undergo this transformation, and they are influenced by several factors. Low sublimation properties are characterized by a low vapor pressure, along with a predetermined sublimation temperature range in which sublimation occurs. In embodiments of the disclosure, the sublimation properties of the ER-ER-ESM 302 are set to a predetermined level. In some embodiments of the disclosure, the predetermined sublimation level is a low predetermined sublimation level that is set by a low vapor pressure level and the predetermined sublimation temperature range. In embodiments of the disclosure, the predetermined vapor pressure level is a low vapor pressure, where a low vapor pressure is a vapor pressure below about 1 mmHg at room temperature, where room temperature is a temperature range from ≈20° C. to ≈25° C., or from ≈68 ° F. to ≈77° F. In embodiments of the disclosure, the predetermined sublimation temperature range includes a temperature above 1300° C. In some embodiments of the disclosure, the predetermined sublimation temperature range is above 1300° C. to about 4500° C.

The removability characteristics 306 can include being soluble responsive to an acid. In embodiments of the disclosure, the acid is a weak acid (e.g., acetic acid). A “weak acid” refers to an acid that does not completely dissociate in solution. This is more about the acid's dissociation properties than a specific concentration of the acid. Weak acids only partially ionize in water, meaning that at equilibrium, both the undissociated acid and its ions are present. In embodiments of the disclosure, the weak acid has an acid dissociation constant (Ka) below a predetermined level. In embodiments of the disclosure the predetermined level of the Ka is a low Ka. In embodiments of the disclosure, the low Ka is a Ka below =1×10 5⁻at room temperature, where room temperature is a temperature range from ≈20° C. to ≈25 C., or from ≈68°F. to ≈77° F.

The removability characteristics 308 can include being soluble responsive to water. In some embodiments of the disclosure, the water of the removability characteristic 308 can be plain water. In this disclosure, plain water is water that is substantially free from significant additives or impurities, but can include additives and/or treatments commonly included in municipal drinking water. Examples of such additives and treatments include chlorine/chloramine (used for disinfection to kill harmful bacteria and pathogens in the water supply); fluoride (added to promote dental health and reduce tooth decay); minerals (natural minerals like calcium or magnesium, which can enhance taste and provide health benefits; pH adjusters (substances like sodium hydroxide or sulfuric acid used to maintain the water's pH balance); and anti-corrosion agents (chemicals such as phosphates can be included in plain water to prevent pipe corrosion, ensuring safe delivery of water).

In some embodiments of the disclosure, the water of the removability characteristic 308 can be deionized water, which is used in IC fabrication operations such as CMP to prevent contamination. Deionized water is characterized by being substantially free from ions and impurities; a substantially neutral pH (e.g., pH of about 7); and very low conductivity due to the general absence of ions. Deionized water is generally unreactive but can dissolve certain substances and gases, which can lower its pH. Because deionized water is reactive, its properties start to change as soon as it is exposed to air. Deionized water has a pH of about 7 when it is delivered, but as soon as it comes into contact with carbon dioxide from the air, the dissolved CO₂ reacts to produce H⁺ and HCO₃⁻, thereby driving the pH closer to 5.6.

In some embodiments of the disclosure, the water of the removability characteristic 308 is distilled water. Distilled water is produced through distillation, which involves boiling water to create steam and then condensing that steam back into liquid form. This process removes many impurities, including minerals, bacteria, and some chemicals. However, some volatile organic compounds (VOCs) can remain if they have a boiling point lower than water.

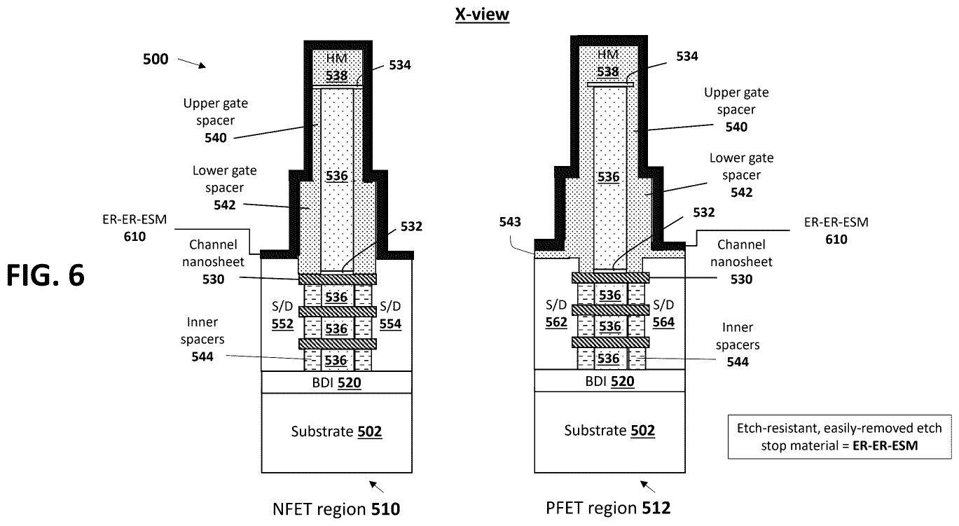

Thus, the ER-ER-ESM 302 is robust (i.e., etch-resistant) based on exhibiting one or more of the etch-resistant characteristics 304A, 304B, 304C; and the ER-ER-ESM 302 is easily removed based at least in part on exhibiting one or more of the removability characteristics 306, 308. In some embodiments of the disclosure, the ER-ER-ESM 302 is applied to an IC-under-fabrication as a conformal layer of the ER-ER-ESM 302 (e.g., conformal layer of ER-ER-ESM 610 shown in FIG. 6).

A non-limiting example of an ER-ER-ESM 302 having various combination of the etch-resistant characteristics 304A, 304B, 304C and the removability characteristics 306, 308 described herein include material containing sufficient magnesium (Mg) to provide the material with one or more of the etch-resistant characteristics 304A, 304B, 304C, including but not limited to magnesium oxide (MgO) and magnesium fluoride (MgF₂), as well as material containing sufficient calcium to provide the material with one or more of the removability characteristics 306, 308, including but not limited to calcium oxide (CaO). FIG. 3B depicts a table 310 illustrating various properties of MgO; and FIG. 3C depicts a table 320 illustrating various properties of MgF₂. Although not listed in tables 310, 320 MgO and MgF₂ are soluble in water (e.g., plain water, deionized water, and/or distilled water) and/or a weak acid. Examples of materials that do not provide both etch-resistant characteristics (e.g., one or more of the etch-resistant characteristics 304A, 304B, 304C) and removability characteristics (e.g., removability characteristics 306, 308) in accordance with embodiments of the disclosure include AlOx, HfOx, LaOx, and the like. In particular, AlOx, HfOx, LaOx are difficult to remove post S/D trench etch in that these materials do not provide at least the removability characteristics 306, 308.

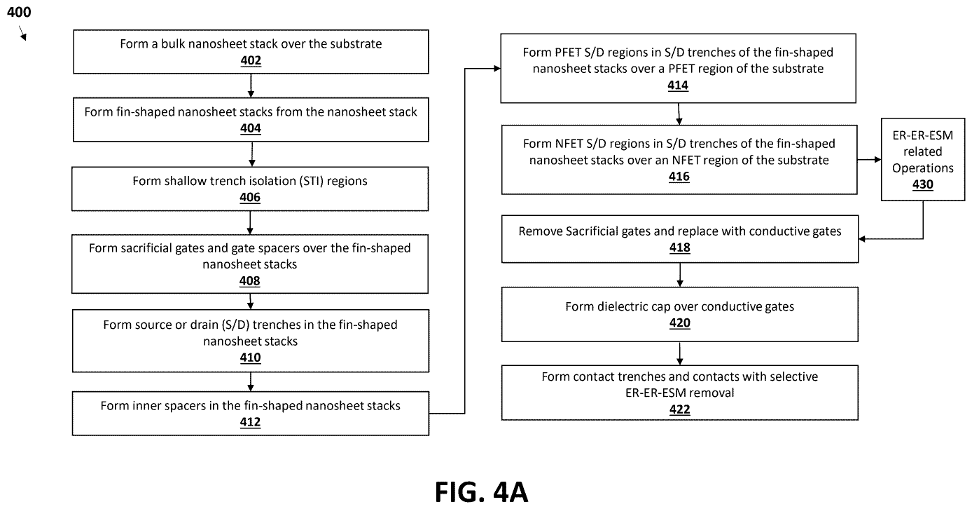

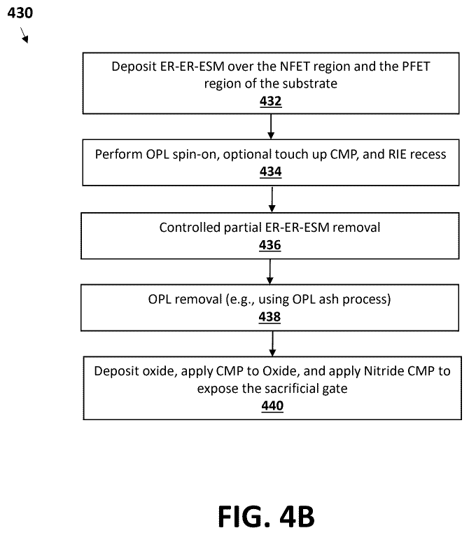

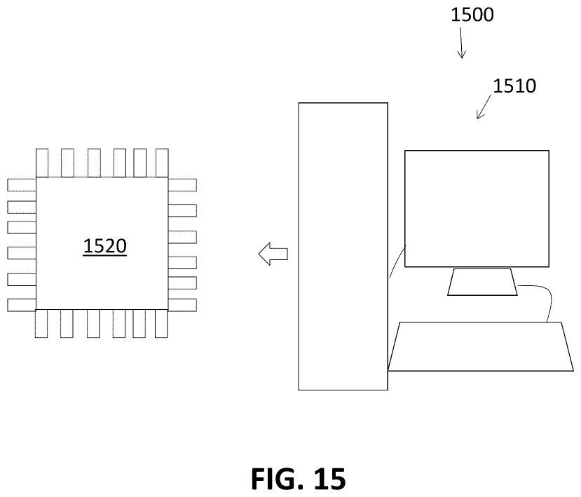

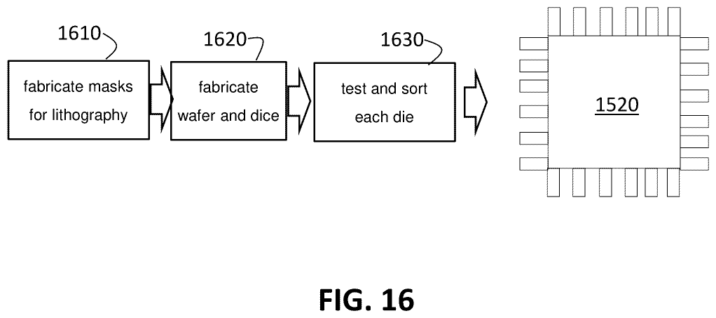

FIG. 4A depicts a flow diagram illustrating a methodology 400 for forming an IC that incorporates the ER-ER-ESM 302 in accordance with embodiments of the disclosure. The operations at blocks 402-416 of the methodology 400 result in an IC structure 500 shown in FIG. 5. In embodiments of the disclosure, the methodology 400 can be performed using a system 1500 (shown in FIG. 15) and can be incorporated in a method of fabricating an IC 1520 (shown in FIG. 16). The methodology 400 forms PFETs in a PFET region 512 of a substrate 502 (shown in FIG. 5), and also forms NFETs in an NFET region 510 of the substrate 502 (shown in FIG. 5). For the sake of brevity, the descriptions of conventional and well-known IC fabrication techniques performed in the methodology 400 may or may not be described in detail herein. Moreover, the various tasks and process steps described in the methodology 400 herein can be incorporated into a more comprehensive procedure or process having additional steps or functionality not described in detail herein. Thus, various operations in the methodology 400 that are well known will only be mentioned briefly herein or will be omitted entirely without providing the well-known process details.

The methodology 400 begins at block 402 by using known IC fabrication operations to form a bulk nanosheet stack (not depicted) over the substrate 502 (shown in FIG. 5). The bulk nanosheet stack includes alternating layers of non-sacrificial nanosheets and sacrificial nanosheets. After downstream fabrication operations, channel nanosheets 530 (shown in FIG. 5) will be formed from the non-sacrificial nanosheets.

In embodiments of the disclosure, the substrate 502 can be a bulk configuration. The substrate 502 can be formed from silicon or it can be formed from materials other than silicon, e.g., silicon-germanium, a III-V compound semiconductor material, and the like. The terms “substrate” or “semiconductor substrate” should be understood to cover all semiconducting materials and all forms of such materials.

The alternating layers of non-sacrificial nanosheets and sacrificial nanosheets can be formed by epitaxially growing one nanosheet layer then the next until the desired number and desired thicknesses of the nanosheet layers are achieved. Epitaxial materials can be grown from gaseous or liquid precursors using, for example, vapor-phase epitaxy (VPE), molecular-beam epitaxy (MBE), liquid-phase epitaxy (LPE), or other suitable process. Epitaxial silicon, silicon germanium, and/or carbon doped silicon (Si: C) silicon can be doped during deposition (in-situ doped) by adding dopants, n-type dopants (e.g., phosphorus or arsenic) or p-type dopants (e.g., boron or gallium), depending on the type of transistor.

In some embodiments of the disclosure, the non-sacrificial nanosheet layers can be Si. In some embodiments of the disclosure, the sacrificial nanosheet layers can be about SiGe 30%. The notation “SiGe 30%” is used to indicate that 30% of the SiGe material is Ge and 70% of the SiGe material is Si. In some embodiments of the disclosure, the Ge percentage in the SiGe implementations of the sacrificial nanosheet layers can be any value, including, for example a value within the range from about 20% to about 45%. The germanium percentage in the sacrificial nanosheet layers is selected to provide etch selectivity between the SiGe sacrificial nanosheet layers and the Si non-sacrificial layers, which facilitates selective removal of the SiGe sacrificial layers is subsequent operations of the methodology 400.

In some embodiments of the disclosure, a bottommost sacrificial layer in the bulk nanosheet stack is provided with etch selectivity different from the other sacrificial layers and the sacrificial layers, which allows the methodology 400 to remove the bottommost sacrificial layer in subsequent operations and replace the bottommost sacrificial layer with a bottom dielectric material that will form a bottom dielectric isolation (BDI) (e.g., BDI 520 shown in FIG. 5).

At block 404, the methodology 400 uses known IC fabrication operations (e.g., patterning and etching) to form the bulk nanosheet stack (not depicted) into fin-shaped nanosheet stacks, which will form the basis for forming the individual nanosheet-based FETs of the IC.

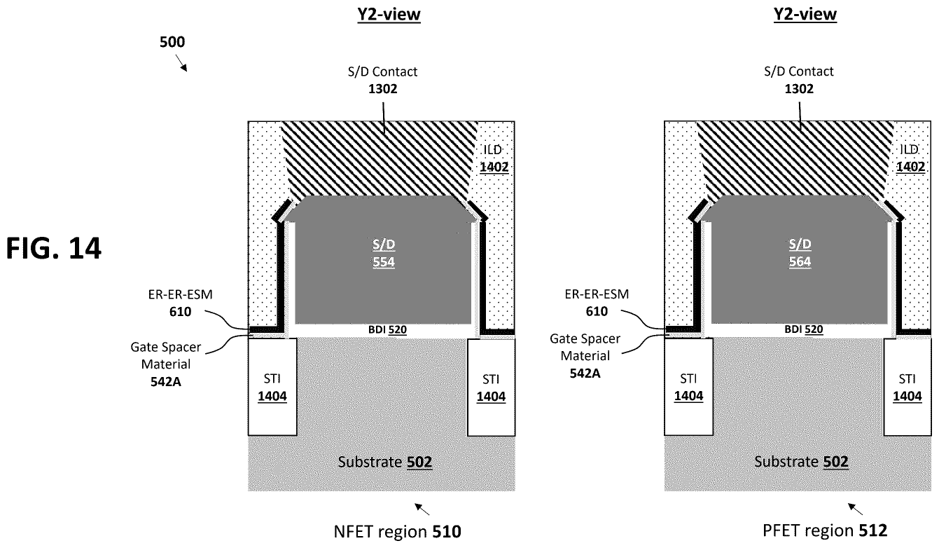

At block 406, the methodology 400 uses known IC fabrication operations (e.g., patterning, etching and deposition) to form shallow trench isolation (STI) regions (e.g., STI 1404 shown in FIG. 14) in and/or over the substrate. The STI regions can be formed by depositing a dielectric material (not shown) over the IC. The dielectric material is planarized or recesses to form STI regions, which prevent electrical current from leaking between adjacent FET devices of the substrate. The STI regions can include any suitable dielectric material, such as, for example, an oxide (e.g., SiO₂).

At block 408, the methodology 400 further uses known IC fabrication operations (e.g., patterning, etching and deposition) to form sacrificial gates (e.g., sacrificial gate regions 536 shown in FIG. 5) and gate spacers (e.g., upper gate spacers 540 and lower gate spacers 542 shown in FIG. 5) for each of the fin-shaped nanosheet stacks. The upper gate spacers 540 can be naturally thinner than the lower gate spacers 542 as the spacer directional reactive ion etching used to form the gate spacers thins down the gate spacer in its upper portion. Prior to formation of the sacrificial gates, a thin layer of gate oxide (e.g., gate oxide 532 shown in FIG. 5) is deposited over the fin-shaped nanosheet stacks. The sacrificial gates (e.g., sacrificial gate regions 536 shown in FIG. 5) can be formed by depositing a sacrificial gate material (not shown) over the gate oxide. A hard mask (HM) layer is deposited over the sacrificial gate material, patterned, and etched to form the sacrificial gates. In some embodiments of the disclosure, the sacrificial gate material can be polycrystalline Si or amorphous Si (a-Si).

At block 408, the methodology 400 can also perform the previously-described operations of removing the bottommost sacrificial layer from the fin-shaped nanosheet stacks and replacing the bottommost sacrificial layer with a bottom dielectric material that will form the bottom dielectric isolation (BDI) (e.g., BDI 520 shown in FIG. 5). The BDI provides dielectric isolation between the fin-shaped nanosheet stacks and the substrate (e.g., substrate 502 shown in FIG. 5).

At block 408, the methodology 400 further uses known IC fabrication operations to form the gate spacers by, for example, depositing dielectric material in open spaces of the IC then etching the dielectric material to form the gate spacers on sidewalls of the sacrificial gates. In embodiments of the disclosure, the dielectric material can be any suitable dielectric material, including, for example, silicon oxide, silicon nitride, silicon oxynitride, SiBCN, SiOCN, SiOC, or any suitable combination of those materials. In some embodiments of the disclosure, the gate spacers can be a low-k dielectric material. The dielectric material used to form the BDI and the gate spacers can be deposited using ALD, CVD, or any other suitable deposition technique. Any excess deposited dielectric material can be removed by a suitable selective isotropic etching process.

At block 410, the methodology 400 uses known IC fabrication operations to form source or drain (S/D) trenches in the fin-shaped nanosheet stacks. The known IC fabrication operations can include etching the portions of fin-shaped nanosheet stacks that are not covered by the sacrificial gates and the gate spacers, thereby forming S/D trenches that each extends through the fin-shaped nanosheet stacks. The S/D trenches provide access to end regions of the sacrificial nanosheets.

At block 412, the methodology 400 uses known IC fabrication operations to partially remove end regions of the sacrificial nanosheets to form end region cavities or inner spacer cavities in which the inner spacers (e.g., inner spacers 544 shown in FIG. 5) are formed. The inner spacers can be silicon nitride, silicoboron carbonitride, silicon carbonitride, silicon carbon oxynitride, or any other type of dielectric material (e.g., a dielectric material having a dielectric constant k of less than about 5).

As previously noted, the methodology 400 forms PFETs in a PFET region of the substrate (e.g., PFET region 512 of the substrate 502 shown in FIG. 5), and also forms NFETs in an NFET region of the substrate (e.g., NFET region 510 of the substrate 502 shown in FIG. 5). Up to block 414, the fabrication operations in the PFET region and the NFET region have been substantially the same. However, after block 412, the methodology 400 must form doped S/D regions, which are different for PFETs and NFETs. Accordingly, at block 414, the methodology 400 covers the NFET region of the substrate (e.g., by applying a blocking mask), performs IC fabrication operations to form PFET doped S/D regions in the S/D trenches located in the PFET region, and uncovers the NFET region of the substrate (e.g., by removing the blocking mask). In some embodiments of the disclosure, prior to uncovering the NFET region, an extra layer of the gate spacer material is deposited over the PFET region to thicken the gate spacers in the PFET region and provide a layer of gate spacer material over the PFET doped S/D regions to protect the PFET doped S/D regions during the NFET doped S/D fabrication operations that will be performed at block 416. Accordingly, the gate spacers in the PFET region are thicker than the gate spacers in the NFET region. At block 416, the methodology 400 performs IC fabrication operations to form NFET doped S/D regions in the S/D trenches located in the NFET region. The layer of gate spacer material over the PFET doped S/D regions protects the PFET doped S/D regions during the NFET doped S/D fabrication operations that form the NFET doped S/D regions.

The known IC fabrication operations performed at block 414 and block 416 to form doped S/D regions include an epitaxial growth process that grows the doped S/D regions from exposed ends of the non-sacrificial nanosheets and/or from the exposed substrate when the optional BDI layer (e.g., BDI 520 shown in FIG. 5) is absent. In embodiments of the disclosure, the doped S/D regions can be epitaxially grown from gaseous or liquid precursors using, for example, vapor-phase epitaxy (VPE), molecular-beam epitaxy (MBE), liquid-phase epitaxy (LPE), or other suitable process. The doped S/D regions can be epitaxial silicon, silicon germanium, and/or carbon doped silicon (Si:C) that has been doped during deposition (in-situ doped) by adding dopants, n-type dopants (e.g., phosphorus or arsenic) or p-type dopants (e.g., boron or gallium), depending on the type of transistor (NFET or PFET). In addition, n-type and p-type FETs are formed by implanting different types of dopants to the S/D regions to form the necessary junction(s).

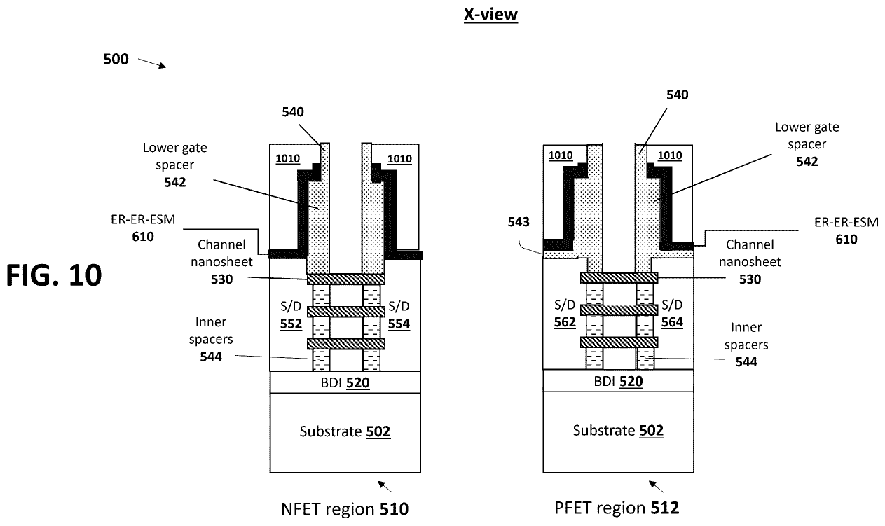

From block 416, the methodology 400 moves to block 430 to perform ER-ER-ESM-related operations in accordance with aspects of the disclosure. A non-limiting example of how the operations at block 430 can be performed is depicted in FIG. 4B, and example structures illustrating the operations performed at block 430 are illustrated at FIGS. 5-14. The operations performed at block 430 are described below with reference to FIG. 4B and FIGS. 5-9; and the operations performed at blocks 418-422 are described with reference to FIGS. 10-14.

FIG. 5 depicts representative portions of the IC structure 500 that is under fabrication using the methodology 400. The instance of the IC structures 500 depicted in FIGS. 5-13 are a cross-sectional views taken along an X-view; and the instance of the IC structures 500 depicted in FIG. 14 is a cross-sectional view taken along a Y2-view. The operations at blocks 402-416 of the methodology 400 result in the IC structures 500 shown in FIG. 5. As shown in FIG. 5, the IC structure 500 at this fabrication stage includes a substrate 502 having an NFET region 510 where NFETs are being formed, along with a PFET region 512 of the substrate 502 where PFETs are being formed. The NFETs in the NFET region 510 include a BDI 520, sacrificial gate regions 536, lower gate spacers 542, upper gate spacers 540, spaced-apart channel nanosheets 530, inner spacers 544, a gate oxide 532, NFET doped S/D regions 552, NFET doped S/D regions 554, a dielectric 534, and a hard mask (HM) 538, configured and arranged as shown. The PFETs in the PFET region 512 include the BDI 520, the sacrificial gate regions 536, lower gate spacers 542, upper gate spacers 540, spaced-apart channel nanosheets 530, inner spacers 544, a gate oxide 532, PFET doped S/D regions 562, PFET doped S/D regions 564, a dielectric 534, and a hard mask (HM) 538, configured and arranged as shown. As previously noted in connection with the description of block 414 of the methodology 400, in some embodiments of the disclosure, prior to uncovering the NFET region 510, an extra layer of the gate spacer material is deposited over the PFET region 512 to thicken the lower gate spacer 542, the upper gate spacer 540 and the HM 538 of the PFETs in the PFET region 512, as well as providing a layer of gate spacer material 543 over the PFET doped S/D regions 562 and the PFET doped S/D regions 564 to protect the PFET doped S/D regions 562 and the PFET doped S/D regions 564 during the operations to form the NFET doped S/D regions 552 and the NFET doped S/D regions 554 that were performed at block 416 of the methodology 400. Accordingly, the lower gate spacers 542, the upper gate spacers 540, and the HM 538 in the PFET region 512 are thicker than the lower gate spacers 542, the upper gate spacers 540, and the HM 538 in the NFET region 510. In some embodiments of the disclosure, the layer of gate spacer material 543 can be removed after forming the NFET doped S/D regions 552 and the NFET doped S/D regions 554 (not shown). In alternative embodiments of the disclosure, the order of forming PFET and NFET S/D regions can be reversed (e.g. NFET S/D regions can be formed first) resulting in the thicker lower gate spacers 542, upper gate spacers 540, and HM 538 in the NFET region 510 and the layer of gate spacer material 543 over the NFET doped S/D regions 552 and the NFET doped S/D regions 554.

FIG. 6 depicts the IC structure 500 after the operations at block 432 (shown in FIG. 4B) have used known IC fabrication operations (e.g., atomic layer deposition (ALD), chemical vapor deposition (CVD), and/or physical vapor deposition (PVD)) to deposit a conformal layer of the ER-ER-ESM 610 over the IC structure 500. The conformal layer of the ER-ER-ESM 610 uses the ER-ER-ESM 302 shown in FIG. 3 having any combination of the etch-resistant characteristics 304A, 304B, 304C and the removability characteristics 306, 308 also depicted in FIG. 3.

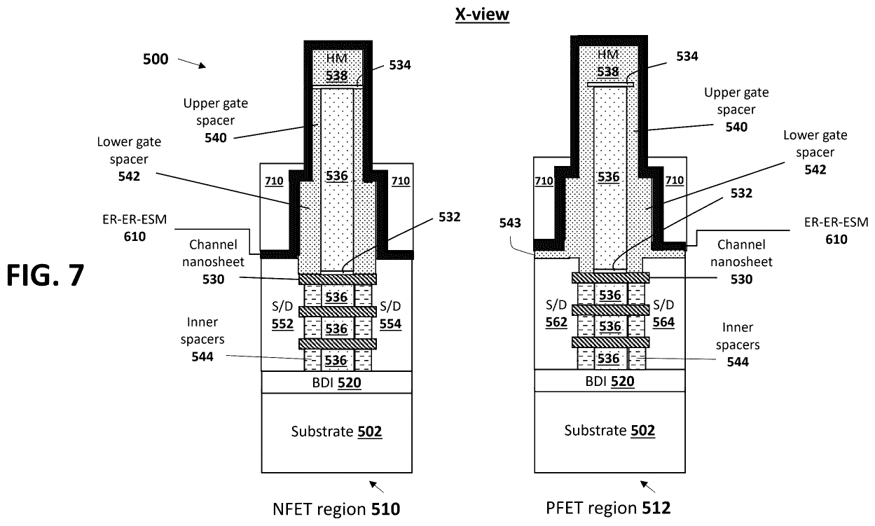

FIG. 7 depicts the IC structure 500 after the operations at block 434 (shown in FIG. 4B) have used known IC fabrication operations to perform an organic planarization layer (OPL) spin-on operation, an optional touch up chemical mechanical planarization (CMP), and a reactive ion etch (RIE) recess to form an OPL structure 710. An OPL is an organic material used in IC fabrication to achieve surface planarization. OPLs can include organic polymers, such as polyimides or other photoresist-like materials. OPLs can be applied using spin coating, where a liquid polymer is deposited on a wafer and spun to create a uniform thin film. Spin-on deposition processes are typically self-planarizing but an optional touch up CMP can be performed to make a planar OPL surface. In some embodiments of the disclosure, an OPL layer is deposited as a relatively thick OPL layer with sufficient thickness to cover the entire IC structure 500. Using the OPL planar surface as the reference, the OPL structure 710 is formed by recessing the OPL planar surface (e.g., by a RIE) to a predetermined depth to uncover HM 538 and portions of upper gate spacers 540, as shown. Accordingly, the OPL structure 710 covers portions of the conformal layer of ER-ER-ESM 610 and leaves other portions of the conformal layer of ER-ER-ESM 610 exposed. The OPL structure 710 effectively buries portions of the conformal layer of ER-ER-ESM 610 to protect the buried portions of the conformal layer of ER-ER-ESM 610 from being removed by the deionized water or weak acid used to remove the unburied portions of the conformal layer of ER-ER-ESM 610. The OPL structure 710 further protects the burred portions of the conformal layer of ER-ER-ESM 610 from any exposure to the deionized water.

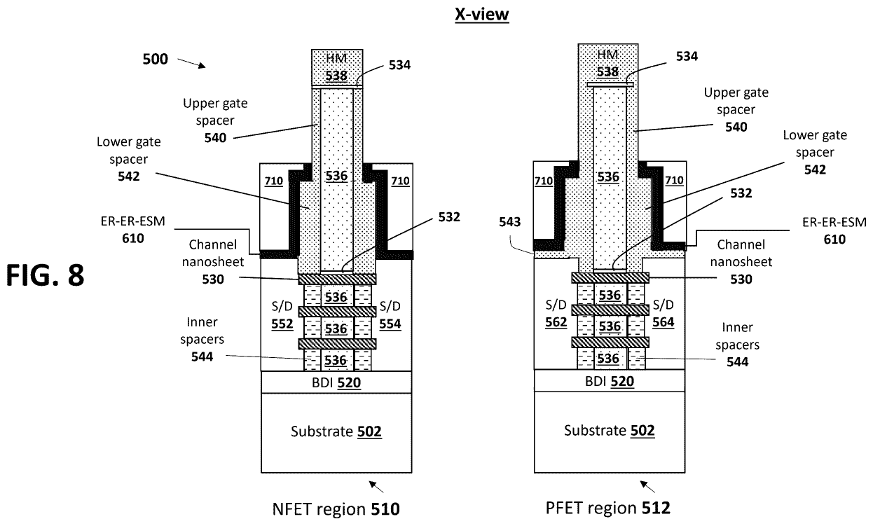

FIG. 8 depicts the IC structure 500 after the operations at block 436 (shown in FIG. 4B) have used IC fabrication operations to perform a controlled partial removal of the exposed or unburied portions (as shown in FIG. 7) of the conformal layer of ER-ER-ESM 610. As previously described herein, the removability characteristics 306, 308 of the conformal layer of ER-ER-ESM 610 can include being soluble responsive to water (e.g., deionized water) and/or a weak acid (e.g., acetic acid) having a low acid dissociation constant (Ka) (e.g., ≈1×10⁻⁵ at room temperature, which is a temperature range from ≈20° C. to ≈25° C. (from ≈68° F. to ≈77° F.)). These removability characteristics 306, 308 make the exposed/unburied portions of the conformal layer of ER-ER-ESM 610 easily removed by water (e.g., deionized water) and/or a weak acid treatment that does not remove any other part of the IC structure 500.

As previously described herein, the water of the removability characteristics 308 can be deionized water. Deionized water is characterized by being substantially free from ions and impurities; a substantially neutral pH (e.g., pH of about 7); and very low conductivity due to the general absence of ions. Deionized water is generally unreactive but can dissolve certain substances and gases, which can lower its pH. Because deionized water is reactive, its properties start to change as soon as it is exposed to air. Deionized water has a pH of about 7 when it is delivered, but as soon as it comes into contact with carbon dioxide from the air, the dissolved CO₂ reacts to produce H⁺ and HCO₃⁻, thereby driving the pH closer to 5.6.

As previously noted, the OPL structure 710 effectively buries portions of the conformal layer of ER-ER-ESM 610 to protect the buried portions of the conformal layer of ER-ER-ESM 610 from being removed by the deionized water and/or weak acid used to remove the unburied portions of the conformal layer of ER-ER-ESM 610. The OPL structure 710 further protects the burred portions of the conformal layer of ER-ER-ESM 610 from any exposure to the deionized water.

FIGS. 6 and 7 illustrate a conformal version of the ER-ER-ESM 610. The term “conformal” as applied to a film means that the film conforms to a given complex topography creating a substantially uniform film over such topography. The deposition process can be also called “conformal,” which simply means that the process has a tendency of depositing “conformal” films of complex topographies with different surfaces. However, after the operations illustrated at FIG. 8 result in a version of the ER-ER-ESM 610 that is not conformal. The opposite to “conformal” (or, equivalently, non-conformal/anti-conformal) is a substantially non-uniform film formed over a complex topography that could be described in alternative terms as self-planarizing, bottom-up, having bread-loafing profile, directionally deposited, selectively deposited, and the like.

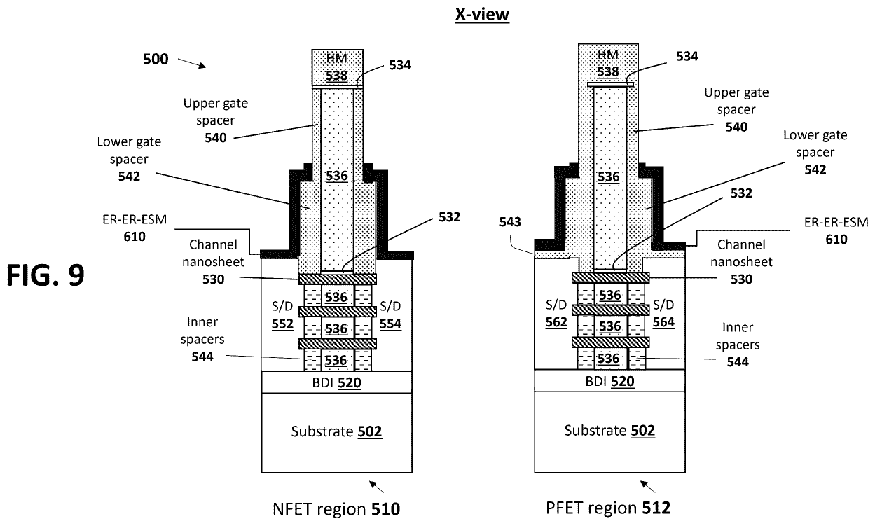

FIG. 9 depicts the IC structure 500 after the operations at block 438 (shown in FIG. 4B) have used known IC fabrication operations to perform an OPL removal process (e.g., using an OPL ash process) to remove the OPL structure 710, thereby exposing portions of the conformal layer of ER-ER-ESM 610. An OPL ash process involves the application of plasma to oxidize and decompose the OPL material, thus turning it into gaseous byproducts that can be safely vented away without leaving residue.

FIG. 10 depicts the IC structure 500 after the operations at block 440 (shown in FIG. 4B) and block 418 (shown in FIG. 4A) have used known IC fabrication operations to deposit an oxide; apply a CMP to the oxide to form dielectric regions 1010; apply a nitride CMP to HM 538 and the upper gate spacers 540 to remove the upper gate spacers 540 and expose the sacrificial gate regions 536; and remove the sacrificial gate regions 536 and gate oxide 532. The IC fabrication operations used to remove the sacrificial gate regions 536 can include a replacement metal gate (RMG) process using, for example, a known etching process, e.g., any suitable wet or gas-phase etch process.

The CMP processes employed at block 440 utilize deionized water rinse to clean the wafer surface from the CMP slurry and CMP byproducts. Because the conformal layer ER-ER-ESM 610 is soluble in deionized water, the amount of polishing is selected to not expose the upper edge of the layer of ER-ER-ESM 610 shown in FIG. 10. The desired or necessary amount of polishing can be accomplished by adjusting the duration of respective CMP steps and/or the recess applied to the OPL layer to form the OPL structure 710 in FIG. 7 (the thickness of OPL structure 710).

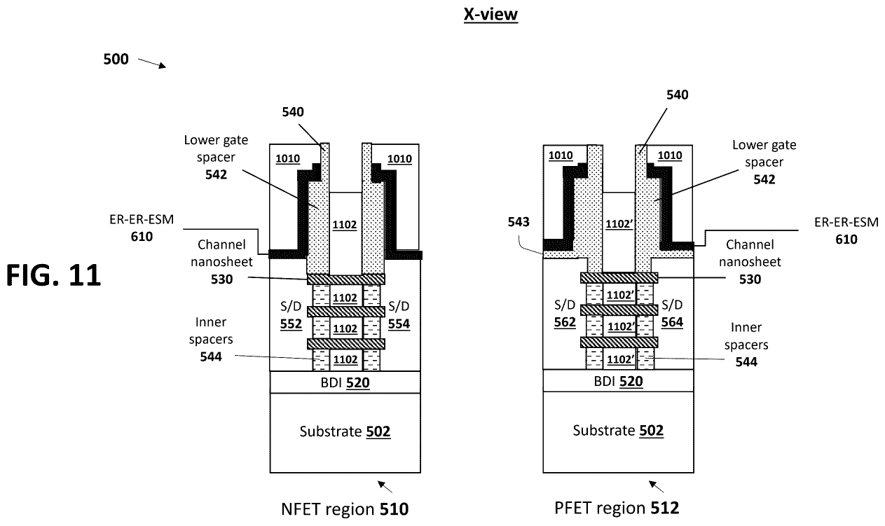

FIG. 11 depicts the IC structure 500 after the operations at block 418 (shown in FIG. 4A) have continued the RMG process by replacing the removed sacrificial gate regions 536 in the NFET region 510 with multi-segmented gate stack structures for NFETs in the NFET region 510, where these NFET multi-segmented gate stack structures are referred to herein as high-k metal gate (HKMG) structures 1102. The RMG process is further continued by replacing the removed sacrificial gate regions 536 in the PFET region 512 with multi-segmented gate stack structures for PFETs in the PFET region 512, where these PFET multi-segmented gate stack structures are referred to herein as HKMG structures 1102′. The HKMG structures 1102, 1102′ each include a primary metal region, a work function metal (WFM) (not shown separately), and a relatively thin (e.g., from about 0.7 nm to about 3 nm) high-k gate dielectric (e.g., hafnium oxide) (not shown separately). The HKMG structures 1102 for NFETs are different from the HKMG structures 1102′ for PFETs. The differences are in the WFM and/or the high-k dielectric chemical structure and are directed to enabling target threshold voltages for NFETs and PFETs. The HKMG structures 1102, 1102′ are over and around respective instances of the channel nanosheets 530 in the NFET region 510 and the PFET region 512 to regulate electron flow through the channel nanosheets 530 between the doped S/D regions (e.g., between NFET doped S/D region 552 and NFET doped S/D region 554; and between PFET doped S/D region 562 and PFET doped S/D region 564).

The primary metal region of the HKMG structures 1102, 1102′can be formed of any suitable conducting material, including but not limited to, doped polycrystalline or amorphous silicon, germanium, silicon germanium, a metal (e.g., tungsten, titanium, tantalum, ruthenium, zirconium, cobalt, copper, aluminum, lead, platinum, tin, silver, gold), a conducting metallic compound material (e.g., tantalum nitride, titanium nitride, tantalum carbide, titanium carbide, titanium aluminum carbide, tungsten silicide, tungsten nitride, ruthenium oxide, cobalt silicide, nickel silicide), carbon nanotube, conductive carbon, graphene, or any suitable combination of these materials. The primary metal region can further include dopants that are incorporated during or after deposition.

Examples of suitable materials for the gate dielectric of the HKMG structures 1102, 1102′ include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k gate dielectric can further include dopants such as lanthanum, aluminum, magnesium. In some embodiments, the gate dielectric can be annealed at elevated temperatures to improve its long-term reliability and to activate additional dopants in the NFET doped S/D region 552, the NFET doped S/D region 554, the PFET doped S/D region 562, and the PFET doped S/D region 562. The peak temperature of these annealing processes can be as high as 1200-1300 degrees Celsius. Accordingly, the melting and boiling points of the conformal layer of ER-ER-ESM 610 is selected to be higher than the peak anneal temperature used in this and other fabrication operations. In some embodiments of the disclosure, the gate dielectric can further include silicon oxide, silicon nitride, silicon oxynitride, or any suitable combination of those materials with high-k dielectric material. In embodiments of the disclosure, the relatively thin gate dielectric is between the channel nanosheets 530 and the primary gate metal region to prevent shorting.

In embodiments of the disclosure, the WFM layers of the HKMG structures 1102, 1102′ can be a nitride, including but not limited to titanium nitride (TiN), titanium aluminum nitride (TiAlN), hafnium nitride (HfN), hafnium silicon nitride (HfSiN), tantalum nitride (TaN), tantalum silicon nitride (TaSiN), tungsten nitride (WN), molybdenum nitride (MoN), niobium nitride (NbN); a carbide, including but not limited to titanium carbide (TiC) titanium aluminum carbide (TiAlC), tantalum carbide (TaC), hafnium carbide (HfC), and combinations thereof (e.g., titanium nitride, titanium aluminum nitride, titanium aluminum carbide, titanium aluminum carbon nitride, and tantalum nitride) and other appropriate metals and conducting metal layers (e.g., tungsten, cobalt, tantalum, aluminum, ruthenium, copper, metal carbides, and metal nitrides). FIG. 11 further depicts the IC structure 500 after the operations at block 418 (shown in FIG. 4A) have used known IC fabrication operations to recess the HKMG structures 1102, 1102′.

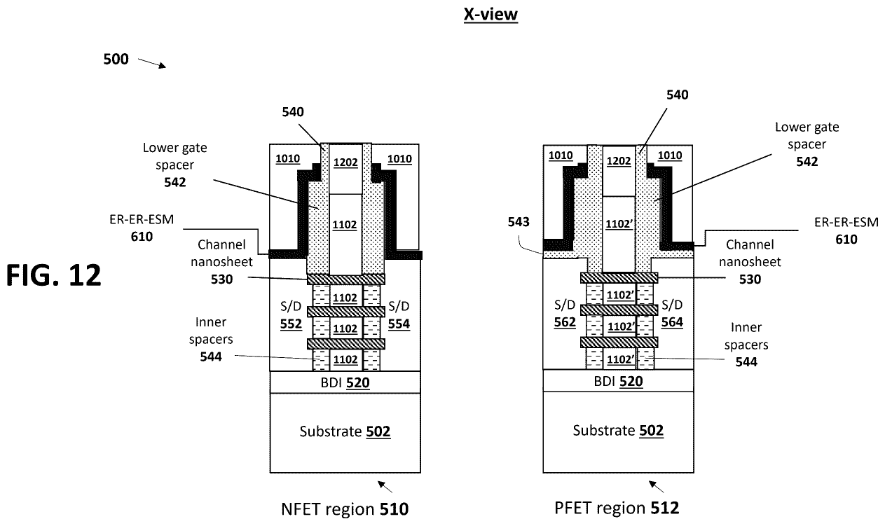

FIG. 12 depicts the IC structure 500 after the operations at block 420 (shown in FIG. 4A) have used known IC fabrication operations to form a self-aligned contact (SAC) gate cap 1202 over the recessed HKMG structures 1102, 1102′. The SAC gate cap 1202 can be formed by depositing (e.g., using ALD) additional fill material above the recessed HKMG structures 1102, 1102′ and between the gate spacers 540, 542, thereby forming the SAC gate caps 1202. In embodiments of the disclosure, the SAC gate caps 1202 can be the same material (e.g., SiN) as the gate spacers 540, 542, or can be different material then the gate spacers 540, 542. The depth of the recess applied to form the recessed HKMG structures 1102, 1102′ defines the vertical thickness of the SAC gate caps 1202. In accordance with embodiments of the disclosure, a bottom edge or a bottom surface of the SAC gate cap 1202 is located below an uppermost end of the layer of ER-ER-ESM 610 shown in FIG. 12. The desired location of the bottom edge or bottom surface of the SAC gate caps 1202 can be accomplished by adjusting the depth of recess applied to form the recessed HKMG structure 1102, 1102′ and/or adjusting a depth of the recess applied to the OPL structure 710 shown in FIG. 7 (e.g., the vertical thickness of OPL structure 710).

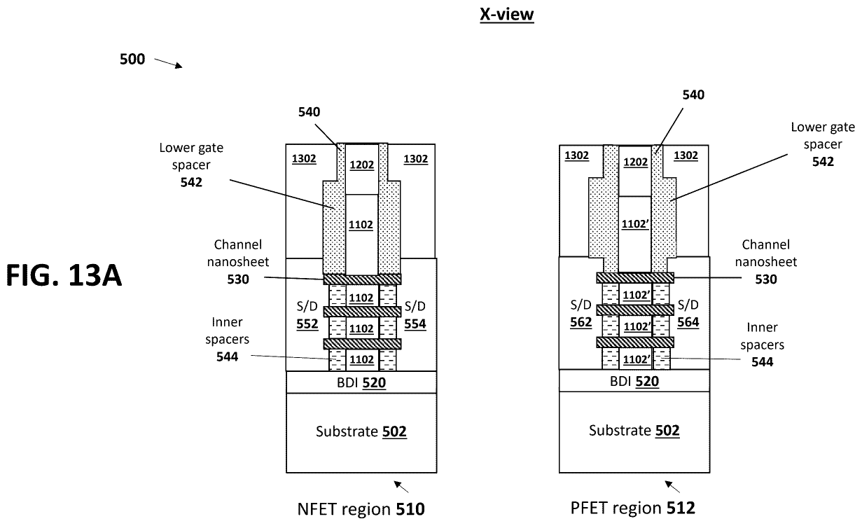

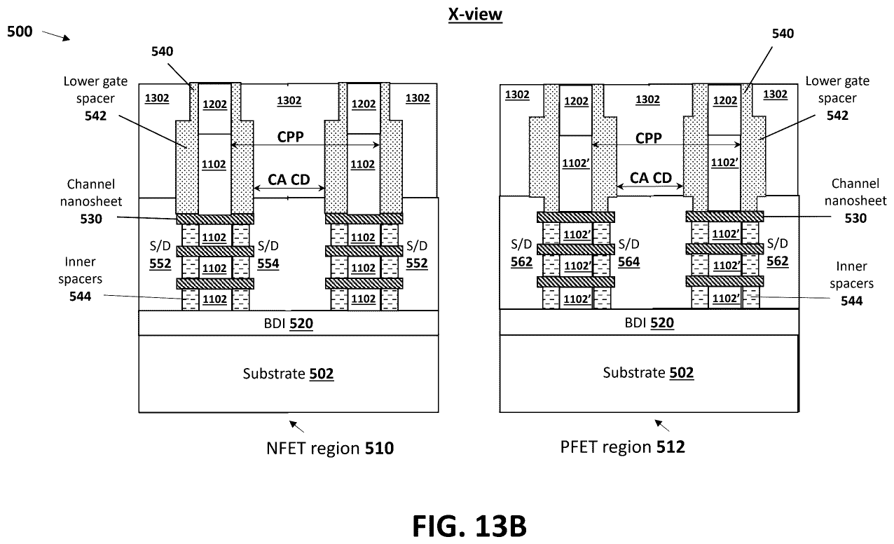

FIG. 13A and FIG. 13B each depicts the IC structure 500 after the operations at block 422 (shown in FIG. 4A) have used IC fabrication operations to form S/D contact trenches through the dielectric regions 1010 with selective ER-ER-ESM removal, followed by a short etch to remove the layer of gate spacer material 543 shown in FIG. 12, then form S/D contacts 1302 in the S/D contact trenches. The known IC fabrication operations for forming S/D contact trenches include trench patterning followed by directional RIE steps with post RIE cleans. In a self-aligned S/D contact formation scheme, S/D contact trenches are formed in between two adjacent gate structures (e.g., between a first instance of the recessed HKMG structure 1102 with SAC gate cap 1202 and gate spacers 540, 542 and a second instance of the HKMG structure 1102 with SAC gate cap 1202 and gate spacers 540, 542) in the NFET region 510 (shown in FIG. 13B). Similarly, in the self-aligned trench formation scheme, S/D contact trenches are formed in between two adjacent gate structures (e.g., between a first instance of the recessed HKMG structure 1102′ with SAC gate cap 1202 and gate spacers 540, 542 and a second instance of the HKMG structure 1102′ with SAC gate cap 1202 and gate spacers 540, 542) in the PFET region 512 (shown in FIG. 13B).

While FIG. 13B shows one self-aligned version of the S/D contacts 1302 formed in between two adjacent gate structures, a typical transistor structure can contain three (3) or more adjacent gate structures with two self-aligned S/D contacts formed on opposite sides of the central instance of the gate structures. In this arrangement, the central instance of the gate structures is the transistor active gate while two adjacent gate structures are faux. The sum of lateral dimensions (physical gate length) of the HKMG structures 1102, 1102′, double the lateral thickness of gate spacer 542, and a width dimension of the S/D contact trench (often referred to as “contact area critical dimension” or CA CD) is the contacted gate pitch also known as the contacted poly pitch (CPP). CPP is a key geometrical factor that defines transistor density in an IC. Reducing CPP through shrinking any of the transistor components is highly beneficial as it leads to a higher transistor density. Because printing of ultra small S/D contact trenches is challenging, the self-alignment scheme of forming S/D contact trenches relies on the etch selectivity between the material of the dielectric regions 1010 and the materials of SAC gate cap 1202 and the gate spacers 542, 540. The S/D contact trenches are printed wider than the target dimension and overlapping with adjacent edges of the gate spacers 540. Then, a contact trench RIE follows the contours of adjacent gate spacers 540, 542 if the difference in etch selectivity between materials is high enough. However, if the difference in etch selectivity between materials drops the gate spacers 540, 542 are thinned down and/or damaged resulting in a poor breakdown-driven IC reliability and/or an electrical short as alluded above. An increase in starting lateral thickness of the gate spacer 542 leads to a penalty in CPP or, equivalently, a penalty in transistor density. Conversely, at a fixed CPP, an increase in starting lateral thickness of the gate spacer 542 leads to a shrinking CA CD and a corresponding penalty in the contact resistance and a poor or reduced transistor performance.

In embodiments of the disclosure, the dielectric regions 1010 (shown in FIG. 12) are an oxide such as SiO, and the S/D contact trenches are formed by applying a fluoride-based etchant (e.g., a fluorine RIE such as SF6, C4F8) to the dielectric regions 1010 to expose a portion of the conformal layer of ER-ER-ESM 610 that is over a portion of a top surface of the SD regions (e.g., NFET doped S/D region 552, NFET doped S/D region 554, PFET doped S/D region 562, and PFET doped S/D region 564). In accordance with embodiments of the disclosure, and as described previously herein, the ER-ER-ESM 610 has etch-resistant characteristics 304A, 304B, 304C (shown in FIG. 3) that prevent the fluoride-based etch used to form the S/D contact trenches from also etching the gate spacers 540, 542 and exposing the HKMG structures 1102, 1102′to the S/D contract trenches and the subsequently formed S/D contacts 1302. At the same time, the exposed material of SAC gate cap 1202 and the gate spacers 542 is thinned down in an expected manner, but it does not result in a degraded breakdown-driven IC reliability or an electrical short because the bottom edge of SAC gate cap 1202 is placed below the upper ends of the layer of ER-ER-ESM layer 610 shown in FIG. 12. Post removal of the layer of ER-ER-ESM 610 shown in FIG. 12 is followed by removal of the layer of gate spacer material 543 (if present), and, prior to metallization, the process flow can include an optional low-k contact spacer formation within S/D contact trenches.

Subsequent to forming the S/D contact trenches, another controlled partial removal of the exposed portions of the conformal layer of ER-ER-ESM 610 is performed to remove the layer of ER-ER-ESM 610 (shown in FIG. 12) that are within the S/D contact trenches to expose a portion of the top surfaces of the S/D regions (e.g., NFET doped S/D region 552, NFET doped S/D region 554, PFET doped S/D region 562, and PFET doped S/D region 564) where the S/D contacts 1302 will land. As previously described herein, the removability characteristics 306 (shown in FIG. 3) of the conformal layer of ER-ER-ESM 610 includes being soluble responsive to a weak acid (e.g., acetic acid) having a low acid dissociation constant (Ka) (e.g., ≈1×10⁻⁵ at room temperature, which is a temperature range from ≈20° C. to ≈25° C. (from ≈68° F. to ≈77° F.)). This removability characteristic 306 makes the conformal layer of ER-ER-ESM 610 easily removed by a weak acid treatment that does not remove any other part of the IC structure 500. As also previously described herein, the removability characteristics 308 of the conformal layer of ER-ER-ESM 610 includes being soluble responsive to deionized water. Deionized water is characterized by being substantially free from ions and impurities; a substantially neutral pH (e.g., pH of about 7); and very low conductivity due to the general absence of ions. Deionized water is generally unreactive but can dissolve certain substances and gases, which can lower its pH. Because deionized water is reactive, its properties start to change as soon as it is exposed to air. Deionized water has a pH of about 7 when it is delivered, but as soon as it comes into contact with carbon dioxide from the air, the dissolved CO₂ reacts to produce H⁺ and HCO₃⁻, thereby driving the pH closer to 5.6. This removability characteristic 308 makes the conformal layer of ER-ER-ESM 610 easily removed by a deionized water treatment that does not remove any other part of the IC structure 500.

The removal of the layer of ER-ER-ESM 610 (shown in FIG. 12) from the contact trenches increases the trench width (CA CD) without affecting thickness and chemical structure of the gate spacers 542. This fundamental technical benefit can be used for reducing CPP at constant transistor performance or for increasing transistor performance at constant CPP. In the latter case, rather than improving transistor resistance due to an enlarged CA CD, the volume occupied by the layer of ER-ER-ESM 610 can be replaced with a low-k contact spacer resulting in a reduced transistor capacitance at constant resistance and, consequently, an improved high-frequency alternating current (AC) performance. Portions of the conformal layer of ER-ER-ESM 610 that are not within the S/D contact trenches are not exposed during formation of the S/D contact trenches, so these portions of the conformal layer of ER-ER-ESM 610 are not removed and remain in low electric field regions of the IC structure 500. Portions of the conformal layer of ER-ER-ESM 610 that are not removed and remain in low electric field regions of the IC structure 500 are depicted in the Y2-view of the IC structure 500 shown in FIG. 14 and described in greater detail below.

The S/D contacts 1302 can include contact liners (not shown separately), contact barrier layers (not shown separately), and S/D contact metal. Additionally, the exposed surfaces of NFET doped S/D region 552, NFET doped S/D region 554, PFET doped S/D region 562, and PFET doped S/D region 564 within their associated S/D contact trenches can be modified (not shown separately) after removal of the portion of the conformal layer of ER-ER-ESM 610 and prior to contact metallization. In embodiments of the disclosure, the contact liners and S/D surface modifications are configured to assist in minimizing or reducing contact resistance including bulk/vertical and interfacial components of the S/D contact 1302. The bulk/vertical resistance of the S/D contact 1302 is proportional to the material resistivity and thickness or height of respective conductive elements present in the S/D contact 1302 and inversely proportional to the cross-sectional area of the S/D contact 1302 defined by CA CD. The larger the CA CD, the larger the cross-sectional area of the S/D contact 1302, the smaller the bulk/vertical component of the contact resistance. The interfacial contact resistance is the electrical resistance between the material of the S/D contact 1302 and the S/D material of respective NFET doped S/D region 552, NFET doped S/D region 554, PFET doped S/D region 562, and PFET doped S/D region 564 and the electrical resistance between any conductive layers present in the S/D contact 1302. The interfacial contact resistance is proportional to the respective specific contact resistivity (a material property of the interface between two adjacent conductive materials) and inversely proportional to the interfacial area between these materials. The larger the CA CD, the larger the interfacial area, the smaller the interfacial component of the contact resistance. In embodiments of the disclosure, the surface modification of exposed S/D surfaces can include increasing exposed surface area (the future interfacial area) by either intentional gouging into the NFET doped S/D region 552, NFET doped S/D region 554, PFET doped S/D region 562, and PFET doped S/D region 564 or growing a low-temperature selective epitaxial pedestals, forming S/D surface regions with a very high activation of dopants, and performing cleans to eliminate any native oxide that forms at the exposed S/D surface. In some embodiments of the disclosure, the specific contact resistivity between the material of the S/D contact 1302 and the S/D material of respective NFET doped S/D region 552, NFET doped S/D region 554, PFET doped S/D region 562, and PFET doped S/D region 564 is lower than about 1E-9 Ohm. cm².

In embodiments of the disclosure, the contact liners (e.g., Ti) are conformally and/or selectively deposited on the S/D contact trenches to form silicide regions. Example materials for forming the contact liners include tantalum nitride and tantalum (TaN/Ta), titanium, titanium nitride, cobalt, ruthenium, and manganese. The contact barrier layers can be titanium nitride (TiN), tantalum nitride (TaN), hafnium nitride (HfN), niobium nitride (NbN), tungsten nitride (WN), or combinations thereof, where the contact barrier layers can prevent diffusion and/or alloying of the S/D contact metal with the materials that form the S/D trenches. In various embodiments of the disclosure, the contact barrier layers and/or the contact liners can be conformally deposited in the S/D contact trenches by ALD, CVD, metal-organic chemical vapor deposition (MOCVD), plasma-enhanced chemical vapor deposition (PECVD), or combinations thereof. The S/D contact metal can be tungsten (W), aluminum (Al), copper (Cu), cobalt (Co) or other conductive materials with a low effective resistivity, including, for example, lower than about 25 “μΩ·cm” (microohm-centimeter). The S/D contact metal can also be formed from any of the conductive materials previously described herein as suitable conductive materials for the HKMG structure 1102. In embodiments of the disclosure, the S/D contact metal can be formed conformally by ALD, CVD, and/or PVD. Irrespective of the choice for S/D surface modifications and contact conductive layers and materials, the contact resistance components scale with the contact width CA CD. Removal of the layer of ER-ER-ESM 610 (shown in FIG. 12) from contact trenches increases CA CD and reduces the contact resistance. Known gate contact fabrication methods can be used to form contacts (not shown) extending through the SAC gate caps 1202 to contact the HKMG structures 1102, 1102′.

As previously noted, FIG. 14 depicts a Y2-view of portions of the conformal layer of ER-ER-ESM 610 that are not removed and remain in low electric field regions of the IC structure 500. As shown in FIG. 14, a layer of fill material (e.g., an interlayer dielectric (ILD)) is deposited over the IC structure 500 to form ILD 1402, and the layer of ER-ER-ESM 610 (shown in FIG. 14) is formed over and adjacent to the doped S/D regions (e.g., NFET doped S/D region 552, NFET doped S/D region 554, PFET doped S/D region 562, and PFET doped S/D region 564). In some embodiments, the ILD 1402 is the dielectric regions 1010 shown in FIG. 10. In some embodiments of the disclosure, portions of the same gate spacer material (e.g., a nitride such as SiN) that was deposited and processed to form the lower gate spacers 542 is the gate spacer material 542A, which is shown in FIG. 14 and can be between the layer of ER-ER-ESM 610 (shown in FIG. 140 and a layer of the BDI 520.

In a non-limiting example, the fabrication methods and resulting structure in accordance with aspects of the disclosure allow for or enable scaling CPP to below 40 nm and down to 35 nm. Due to the etch-resistant characteristics of the conformal layer of ER-ER-ESM 610, the thickness of the conformal layer of ER-ER-ESM 610 can be first reduced from 3.5 nm to below 2 nm and then the portions of the conformal layer of ER-ER-ESM 610 in the S/D trenches are removed without any damage to other portions of the transistor due to the easily-removed property of the conformal layer of ER-ER-ESM 610, leading to a gain of 7 nm in CA CD. Accordingly, the CPP can be scaled down by 7 nm at a constant transistor performance. Thus, embodiments of the disclosure enable state-of the-art CPP to be reduced from 42 nm to 35 nm or by 17%.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

FIG. 15 is a block diagram of a system 1500 to perform fabrication methods for selectively incorporating into an IC an etch stop material (e.g., ER-ER-ESM 302) that is robust (e.g., etch-resistant) and easily-removed according to embodiments of the disclosure. The system 1500 includes processing circuitry 1510 used to generate the design that is ultimately fabricated into an IC 1520. The steps involved in the fabrication of the IC 1520 are well-known and briefly described herein. Once the physical layout is finalized, the finalized physical layout is provided to a foundry. Masks are generated for each layer of the IC based on the finalized physical layout. Then, the wafer is processed in the sequence of the mask order. The processing includes photolithography and etch. This is further discussed with reference to FIG. 16.

FIG. 16 is a process flow of a method of fabricating the IC according to exemplary embodiments of the disclosure. Once the physical design data is obtained, the IC 1520 can be fabricated according to known processes that are generally described with reference to FIG. 16. Generally, a wafer with multiple copies of the final design is fabricated and cut (i.e., diced) such that each die is one copy of the IC 1520. At block 1610, the processes include fabricating masks for lithography based on the finalized physical layout. At block 1620, fabricating the wafer includes using the masks to perform photolithography and etching. Once the wafer is diced, testing and sorting each die is performed, at block 1630, to filter out any faulty die.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

The term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “under,” “lower,” “above,” “over,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The terms “about,” “substantially,” “approximately,” and variations thereof, are intended to include the degree of error associated with measurement of the particular quantity based upon the equipment available at the time of filing the application. For example, “about”can include a range of ±8% or 5%, or 2% of a given value.

The phrase “selective to,” such as, for example, “a first element selective to a second element,” means that the first element can be etched and the second element can act as an etch stop.

The terms “etch selectivity” means the rate or speed at which an etching process removes a target material. Two materials that have a different “etch selectivity” with respect to an etchant means where the etchant removes one of the materials (e.g., a target material) at a faster rate than the etchant removes the other material (e.g., an etch stop material).

The term “conformal” (e.g., a conformal layer) means that the thickness of the layer is substantially the same on all surfaces, or that the thickness variation is less than 15% of the nominal thickness of the layer.

References in the specification to terms such as “vertical,” “horizontal,” “lateral,” etc. are made by way of example, and not by way of limitation, to establish a frame of reference. Terms such as “horizontal” and “lateral” refer to a direction in a plane parallel to a top surface of a semiconductor substrate, regardless of its actual three-dimensional spatial orientation. Terms such as “vertical” and “normal” refer to a direction perpendicular to the “horizontal” and “lateral” direction.

As previously noted herein, for the sake of brevity, conventional techniques related to semiconductor device and IC fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor structure according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. An integrated circuit (IC) comprising:
a transistor;
a dielectric region; and
an etch stop material;
wherein a portion of the etch stop material is between a portion of the dielectric region and a portion of a gate spacer material of the transistor; and
wherein the etch stop material is soluble responsive to an etch stop removal material selected from the group consisting of water and an acid.

2. The IC of claim 1, wherein:
the acid comprises a weak acid; and
the weak acid comprises an acid dissociation constant (Ka) at or below about 1×10⁻⁵.

3. The IC of claim 1, wherein:
the transistor comprises a source or drain (S/D);
the S/D is formed in a S/D trench;
the gate spacer material has a first etch rate responsive to an etchant used to form the S/D trench;
the etch stop material has a second etch rate responsive to the etchant used to form the S/D trench; and
the second etch rate is less than the first etch rate.

4. The IC of claim 3, wherein the etch stop material comprises a vapor pressure at or below a predetermined vapor pressure level.

5. The IC of claim 4, wherein the predetermined vapor pressure level is about 1 Torr.

6. The IC of claim 3, wherein the etch stop material further comprise a boiling point above a predetermined boiling point.

7. The IC of claim 6, wherein the predetermined boiling point is above 1300 degrees Celsius.

8. The IC of claim 3, wherein the etch stop material is selected from the group consisting of a magnesium-containing material and a calcium-containing material.

9. The IC of claim 3, wherein:
the transistor further comprises a bottom dielectric;
the portion of the etch stop material is between the portion of the dielectric region and a portion of the S/D; and
the bottom dielectric is between the portion of the etch stop material and a portion of the S/D.

10. An integrated circuit (IC) fabrication method comprising:
forming an etch stop material, wherein a portion of the etch stop material is adjacent a gate spacer of a transistor-under-fabrication (TUF);
forming a dielectric region over and adjacent to the portion of the etch stop material; and
applying an etchant operable to etch a portion of the dielectric region;
wherein the gate spacer has a first etch rate responsive to the etchant;
wherein the etch stop material has a second etch rate responsive to the etchant;
wherein the second etch rate is less than the first etch rate; and
wherein the etch stop material is soluble responsive to an etch stop removal material selected from the group consisting of water and an acid.

11. The IC fabrication method of claim 10, wherein:
the acid comprises a weak acid; and
the weak acid comprises an acid dissociation constant (Ka) at or below about 1×10⁻⁵. 12. The IC fabrication method of claim 10, wherein the etch stop material further comprise a vapor pressure at or below a predetermined vapor pressure level.

13. The IC fabrication method of claim 12, wherein the predetermined vapor pressure level is about 1 Torr.

14. The IC fabrication method of claim 10, wherein the etch stop material further comprise a boiling point above a predetermined boiling point.

15. The IC fabrication method of claim 14, wherein the predetermined boiling point is 1300 degrees Celsius.

16. The IC fabrication method of claim 10, wherein the etch stop material further comprises:
a vapor pressure below a predetermined vapor pressure level; and
a boiling point above a predetermined boiling point.

17. The IC fabrication method of claim 16, wherein:
the predetermined vapor pressure level is 1 Torr; and
the predetermined boiling point is 1300 degrees Celsius.

18. An integrated circuit (IC) fabrication method comprising:
forming a transistor comprising a gate spacer and a source or drain (S/D);
forming an etch stop material;
forming a dielectric region over the S/D, wherein a first portion of the etch stop material is between a portion of the dielectric region and a portion of the gate spacer; and
forming a S/D contact trench in the dielectric region by applying an etchant operable to etch the dielectric region;
wherein the first portion of the etch stop material prevents the portion of the gate spacer from being contacted by the etchant; and
wherein the etch stop material is soluble responsive to an etch stop removal material selected from the group consisting of water and an acid.

19. The IC fabrication method of claim 18 further comprising, subsequent to forming the S/D trench, removing the first portion of the etch stop material.

20. The IC fabrication method of claim 19, wherein, subsequent to removing the first portion of the etch stop material, a second portion of the etch stop material remains in an IC formed by the IC fabrication method.

21. The IC fabrication method of claim 18, wherein:
the acid comprises a weak acid;
the weak acid comprises an acid dissociation constant (Ka) at or below about 1×10⁻⁵; and
the etch stop material further comprise a boiling point above 1300 degrees Celsius.

22. An integrated circuit (IC) fabrication method comprising:
forming a transistor comprising a gate spacer and a source or drain (S/D);
conformally depositing a layer of an etch stop material;
forming a first dielectric region over the S/D, wherein a first portion of the layer of the etch stop material is between a portion of the first dielectric region and a portion of the gate spacer;
forming a S/D contact trench in the first dielectric region by applying an etchant operable to etch the first dielectric region;
wherein the first portion of the layer of the etch stop material prevents the portion of the gate spacer from being contacted by the etchant;
wherein an etch rate of the etch stop material responsive to the etchant is less than an etch rate of the gate spacer responsive to the etchant; and
wherein the etch stop material is soluble responsive to an etch stop removal material selected from the group consisting of water and an acid; and
subsequent to forming the S/D trench, removing the first portion of the layer of the etch stop material;
wherein, subsequent to removing the first portion of the layer of the etch stop material, a second portion of the layer of the etch stop material remains in a final version of the IC.

23. The IC fabrication method of claim 22, wherein:
acid comprises a weak acid;
the weak acid comprises an acid dissociation constant (Ka) at or below about 1×10⁻⁵; and
the etch stop material comprise a boiling point above 1300 degrees Celsius.

24. An integrated circuit (IC) fabrication method comprising:
forming a transistor comprising a gate spacer, a source or drain (S/D), and a gate cap;
forming a layer of an etch stop material;
forming a first dielectric region over the S/D, wherein a first portion of the layer of the etch stop material is between a portion of the first dielectric region and a portion of the gate spacer;
forming a S/D contact trench in the first dielectric region by applying an etchant operable to etch the first dielectric region;
wherein the first portion of the layer of the etch stop material prevents the portion of the gate spacer from being contacted by the etchant;
wherein an etch rate of the etch stop material responsive to the etchant is less than an etch rate of the gate spacer responsive to the etchant; and
wherein the etch stop material is soluble responsive to an etch stop removal material selected from the group consisting of water and an acid; and
subsequent to forming the S/D trench, removing the first portion of the layer of the etch stop material;
wherein a bottom surface of the gate cap is vertically lower than a top surface of an end region of a second portion of the layer of the etch stop material.

25. The IC fabrication method of claim 24 further comprising removing the second portion of the layer of the etch stop material, wherein, subsequent to removing the second portion of the layer of the etch stop material, a third portion of the layer of the etch stop material remains in a final version of an IC formed by the IC fabrication method.
